(19) United States
(12) Patent Application Publication
(10) Pub. No.: US 2008/0035956 A1
(43) Pub. Date: Feb. 14, 2008

(54) Memory device with non-orthogonal word and bit lines

(75) Inventor: H. Montgomery Manning, Eagle, ID (US)

Correspondence Address: SCHWEGMAN, LUNDBERG & WOESSNER, P.A., P.O. BOX 2938, MINNEAPOLIS, MN, 55402, US

(73) Assignee: Micron Technology, Inc.

(21) Appl. No.: 11/503,616

(22) Filed: Aug. 14, 2006

(51) Int. Cl. H01L 27/108; H01L 21/8242

(52) U.S. Cl. 257/202; 438/239; 438/587; 257/296

(57) ABSTRACT

A semiconductor memory device such as a dynamic random access memory (DRAM) has substantially non-orthogonal word and bit lines. For a given memory cell size, such as six square lithographic features (6F²), the non-orthogonal layout allows for larger-pitch word and bit lines when compared to the orthogonal layout of the word and bit lines.

### TECHNICAL FIELD

This document relates generally to semiconductor integrated circuit technology and particularly to semiconductor memory devices with word and bit lines extending in non-orthogonal directions.

### BACKGROUND

Semiconductor memory has been an essential device in many electronic systems. One example of a semiconductor memory device is a random access memory (RAM) device. A RAM device allows the user to execute both read and write operations on its memory cells that are each a device for storing a data bit. Typical examples of RAM devices include dynamic random access memory (DRAM) and static random access memory (SRAM).

A memory device such as a DRAM includes memory cell arrays. Each cell array includes memory cells connected to word lines and bit lines (also referred to as digit lines). The bit lines are used for writing data into and reading data from the memory cells. The word lines are address lines used for selecting the memory cells to which data are written into and from which the data are read from. The amount of memory cells in a memory device determines the data storage capacity of the memory device. Given a specified data storage capacity, such as in gigabits, the size and topology of the physical structures inside the memory device, including the memory cells, bit lines, word lines, and other components such as sense amplifiers and decoders, determine the size of the memory device.

Miniaturization of electronic systems and increasing need for larger memory capacity (such as multi-gigabits), among other reasons, require reduction in size of the physical structures inside a memory device. The size of each physical structure of a memory device is typically described by the size of electrically conductive lines (word and bit lines) in terms of lithographic feature size (F). The lithographic feature size (F) is one half of the minimum pitch, i.e., one half of the sum of the width of one of the electrically conductive lines and the width of the isolation space between the electrically conductive lines. A 6F² memory cell refers to a memory cell that has an area of 6 square lithographic features. For example, a 6F² memory cell has a length of 3F and a width of 2F. For manufacturability or reliability reasons, the minimum feature size should not go beyond the resolution of the lithographic tool. Additionally, a higher resolution requirement generally means a higher cost for manufacturing a memory device.

There is a need to reduce the size of memory devices while ensuring their manufacturability and reliability and maintaining a reasonable cost.

### BRIEF DESCRIPTION OF THE DRAWINGS

The drawings illustrate generally, by way of example, but not by way of limitation, various embodiments discussed in the present document.

FIG. 1 is a top view of a semiconductor die fragment illustrating an embodiment of a portion of a memory device having non-orthogonal word and bit lines.

FIG. 2 is a top view of a semiconductor die fragment illustrating an embodiment of the layout of a subsection of the memory device.

FIG. 3 is a schematic/block diagram illustrating an embodiment of portions of a circuit of the memory device.

FIG. 4 is a block diagram illustrating an embodiment of a processor-based system utilizing the memory device.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. References to “an”, “one”, or “various” embodiments in this disclosure are not necessarily to the same embodiment, and such references contemplate more than one embodiment. The following detailed description provides examples, and the scope of the present invention is defined by the appended claims and their legal equivalents.

This document discusses semiconductor memory devices having a cell array topology including substantially non-orthogonal word and bit lines. In various embodiments, an angle between the word and bit lines is substantially less than 90 degrees. For a given memory cell size, such as 6F², the non-orthogonal layout of the word and bit lines allows for larger-pitch electrically conductive lines when compared to the orthogonal layout of the word and bit lines. This lowers the requirement on the resolution of the lithographic tool, thereby ensuring manufacturability and device reliability, as well as lowering cost of device manufacturing. It also reduces parasitic capacitances.

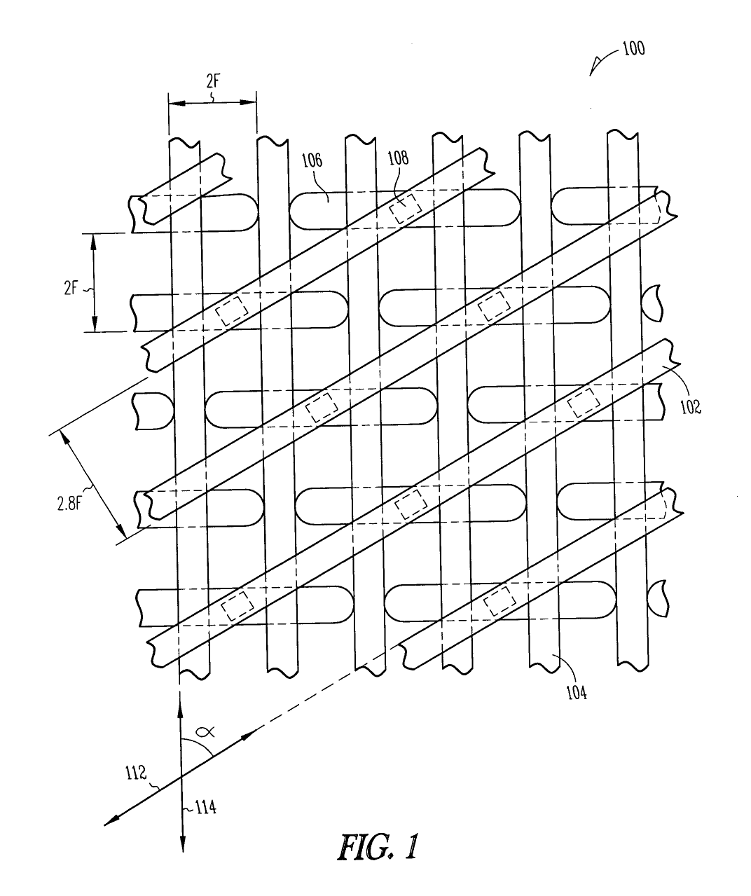

FIG. 1 is a top view of a semiconductor die fragment illustrating an embodiment of a portion of a memory device 100. As illustrated in FIG. 1, a cell array of memory device 100 includes bit lines 102, word lines 104, active areas 106, and bit line contacts 108. Bit lines 102 extend in a direction 112. Word lines 104 extend in another direction 114. Bit lines 102 are substantially non-orthogonal to word lines 104. That is, the angle α between direction 112 and direction 114 is substantially smaller then 90 degrees. Active areas 106 include lines running generally perpendicular to word lines 104. Transistors are formed in each active area. The transistors electrically couple the memory cells to bit lines 102.

In one embodiment, the angle is between approximately 40 and 70 degrees. In a specific embodiment, the angle is approximately 63 degrees.

In one embodiment, word lines 104 are at approximately 2F pitch and each have a width of approximately 1F. The bit lines are at approximately 2.8F pitch and each have a width of approximately 1F. Active areas 106 are at approximately 2F pitch and each have a width of approximately 1F. This allows manufacturing of 6F² memory cells with the minimum lithographic feature pitch of 2F and requires a lithographic resolution of 1F. Compared to 6F² memory cells with orthogonal word and bit lines, bit lines 102 of memory device 100 are at a larger pitch, which reduces the stress on lithography capabilities, thereby providing for better manufacturing-related device reliability, and reduces bit line capacitance. While 6F² memory cells are specifically discussed as a specific example, the structure of non-orthogonal word and bit lines as discussed in this document is also applicable in 8F² memory cells as well as memory cells of other lithographic sizes.

In one embodiment, memory device 100 includes bit lines and word lines that are substantially straight along their entire lengths. That is, the cell array topology as illustrated in FIG. 1 represents the word and bit line layout for an entire cell array of memory device 100. In another embodiment, memory device 100 includes bit lines and word lines that are substantially straight in portions of their lengths. That is, the topology as illustrated in FIG. 1 represents the word and bit line layout for portions of a cell array of the memory device.

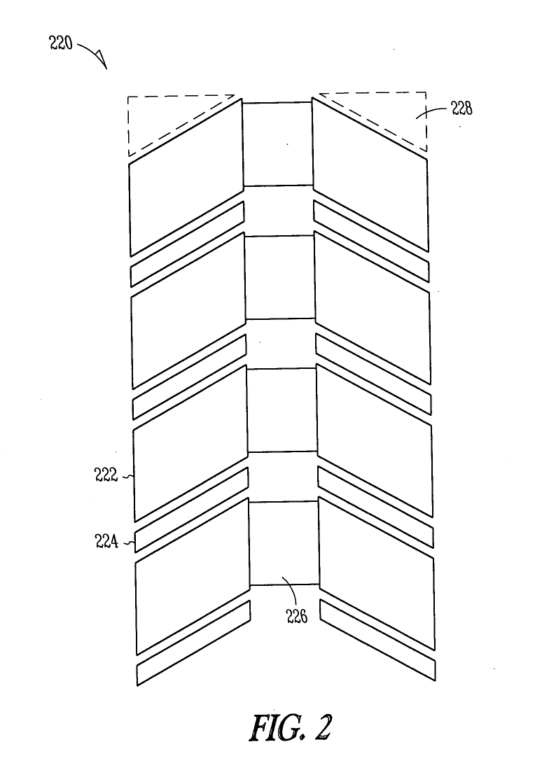

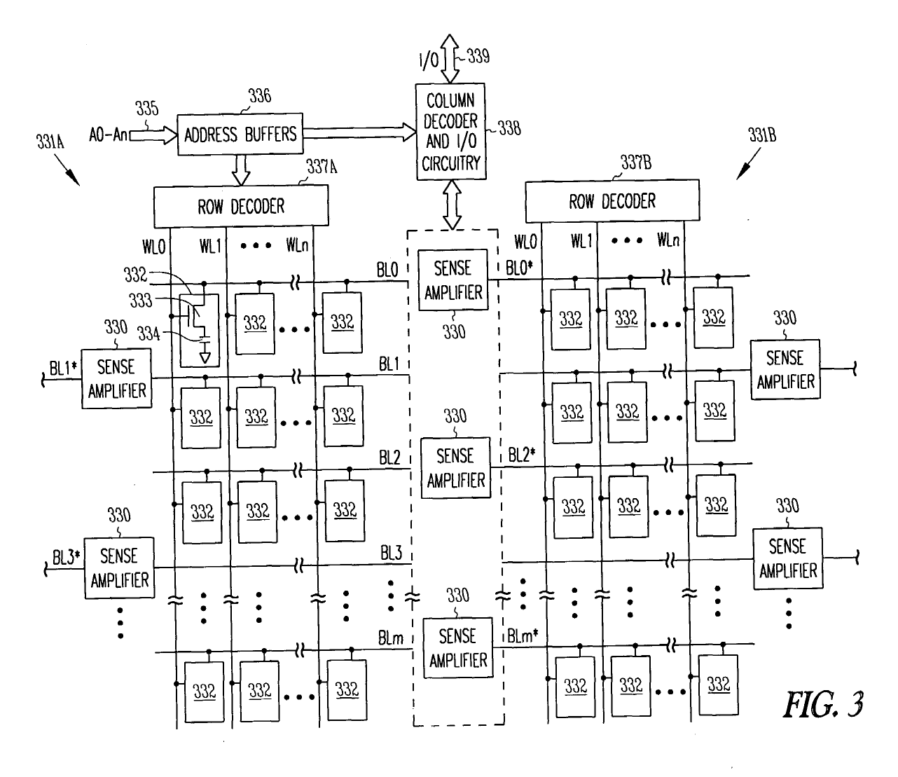

FIG. 2 is a top view of a semiconductor die fragment illustrating an embodiment of a subsection of a die 220 of memory device 100. The illustrated portions of die 220 include memory cell arrays 222, row decoders 224, and sense amplifiers 226. Functions of such components of memory device 100 are discussed below, with reference to FIG. 3.

As illustrated in FIG. 2, die 220 includes columns of memory cell arrays 222 and columns of sense amplifiers 226. Row decoders 224 are each coupled to at least one of the memory cell arrays 222. While the layout of sense amplifiers is similar to that of memory cells with orthogonal word and bit lines, each of memory cell arrays 222 is not generally rectangular as in the case of a typical memory cell array with orthogonal word and bit lines, and the layout of row decoders 224 conforms to the angle of the edge of memory cells 222. Memory cells 222 and row decoders 224 may each have an approximate surface shape that is a substantially non-rectangular parallelogram. The parallelogram has an angle that is approximately equal to the angle α. Such a layout results in a lost area 228 at the edge of die 220. However, this loss is very small compared to the overall size of die 220. In one embodiment, the inefficiency due to lost area 228 is partially gained back by the use of relatively large pitch bit lines because it allows for elimination of unused bit lines on the outside cell arrays and/or the use of smaller sense amplifiers. In this embodiment, the overall size of memory device 100 may be smaller than a memory device of the same storage capability but with orthogonal word and bit lines.

In an alternative embodiment, the locations of row decoders 224 and sense amplifiers 226 are switched in the layout of die 220. In other words, when FIG. 2 illustrates this alternative embodiment, elements 224 represent sense amplifiers, and elements 226 represent row decoders.

FIG. 3 is a schematic/block diagram illustrating an embodiment of portions of a memory circuit of memory device 100 discussed above with reference to FIGS. 1 and 2. In one embodiment, the memory circuit is a DRAM circuit. While an “open” memory array architecture is illustrated in FIG. 3 as an example, the memory cell array topology illustrated in FIGS. 1 and 2 and discussed above can be applied to “folded” or other memory array architectures. While the memory circuit illustrated in FIG. 3 is presented as a specific example, the memory cell array topology illustrated in FIGS. 1 and 2 and discussed above is applicable to implementation of any memory circuit that includes a grid of word and bit lines.

The memory circuit includes memory arrays 331A and 331B including columns and rows of memory cells 332. As illustrated in FIG. 3, memory arrays 331A and 331B have m columns and n rows, with pairs of complementary bit lines BL0/BL0*-BLm/BLm* and word (address) lines WL0-WLn. Each of memory cells 332 is identified by one unique combination of a bit line BL (selected from BL0-BLm) or BL* (selected from BL0*-BLm*) and a word line WL (selected from WL0-WLn). After being fabricated as a semiconductor die of memory device 100, bit lines BL0/BL0*-BLm/BLm* and word lines WL0-WLn has the topology illustrated as bit lines 102 and word lines 104 in FIG. 1.

Complementary bit line pairs BL0/BL0*-BLm/BLm* are used for writing data into and reading data from memory cells 332. Word lines WL0-WLn are address lines used for selecting the memory cells to which data are written into and from which the data are read from. Address buffers 336 receive address signals A0-An from address lines 335 connected to an external controller, such as a microprocessor coupled to the memory circuit. In response, address buffers 336 control one of row decoders 337A-B and column decoder and input/output circuitry 338 to access memory cells 332 selected according to address signals A0-An. Data provided at data input/outputs 339 are capable of being written into memory arrays 331A and 331B. Data read from memory arrays 331A and 331B are applied to data input/outputs 339. Memory cells 332 each include a switch 333 and a storage capacitor 334. In one embodiment, switch 333 includes an n-channel field effect transistor, such as an n-channel metal-oxide semiconductor field-effect transistor (n-channel MOSFET, also referred to as NMOS transistor). The NMOS transistor has a drain terminal coupled to a BL (selected from BL0-BLm) or a BL* (selected from BL0*-BLm*), a source terminal coupled to storage capacitor 334, and a gate terminal coupled to a WL (selected from WL0-WLn).

To write or read data, address buffers 336 receive an address identifying a column of memory cells and select one of the word lines WL0-WLn according to the address. Row decoder 337A or 337B activates the selected word line to activate switch 333 of each cell connected to the selected word line. Column decoder and input/output circuitry 338 selects the particular memory cell for each data bit according to the address. To write data, each data bit at data input/outputs 339 causes storage capacitor 334 of one of the selected cells to be charged, or discharged, to represent the data bit. To read data, a data bit stored in each of the selected cells, as represented by the charge state of storage capacitor 334 of the selected cell, is transferred to data input/outputs 339.

Sense amplifiers 330 are each coupled between a complementary bit line pair, BL and BL*. Storage capacitor 334 in each of memory cells 332 has a small capacitance and holds a data bit for a limited time as the capacitor discharges. Sense amplifiers 330 are used to “refresh” memory cells 332 by detecting and amplifying signals each representing a stored data bit. The amplified signals recharge the storage capacitors and hence maintain the data in memory cells 332.

The same word lines WLx (x=0, 1, . . . n) extending from row decoder 337A or 337B cannot be selected at the same time to activate the corresponding memory cells in both memory arrays 331A and 331B. When a memory cell in memory array 331A is active, its corresponding memory cell in memory array 331B is inactive to act as a reference line to the corresponding sense amplifiers 330. Likewise, when a memory cell in memory array 331B is active, its corresponding memory cell in memory array 331A is inactive to act as a reference line to the corresponding sense amplifiers 330.

To form memory device 100 having the topology illustrated in FIG. 1, data storage capacitors are formed on a semiconductor wafer. A transistor is formed in each active area. Word lines 104 are formed as parallel electrically conductive lines running a first direction, and bit lines are formed as parallel electrically conductive lines running a second direction. The first direction is substantially non-perpendicular to the second direction. The angle between the first direction and the second direction is the angle α as shown in FIG. 1. In various embodiments, the actual angle α is chosen based on the layout and geometry of various components of memory device 100. Each transistor has a source terminal electrically connected to one of the storage capacitors, a drain terminal electrically connected to one of the bit lines, and a gate terminal electrically connected to one of the word lines.

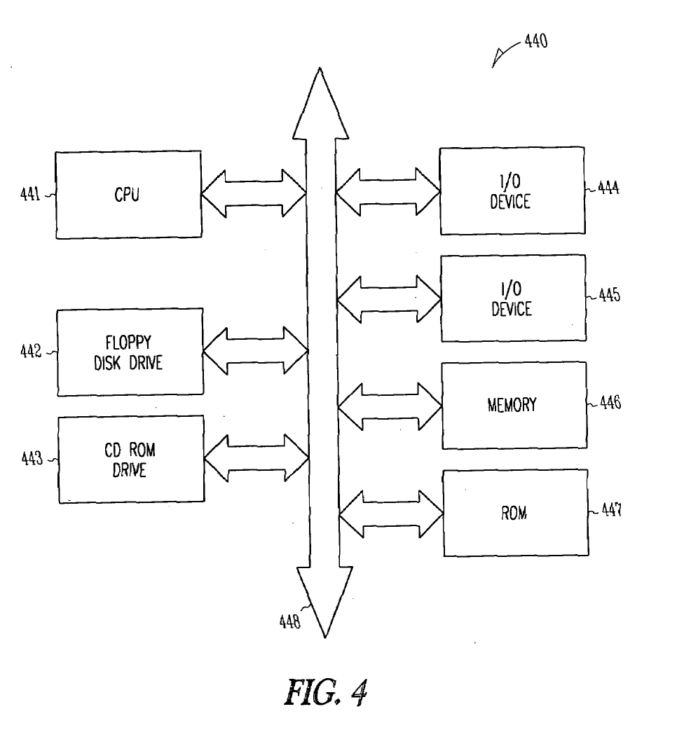

FIG. 4 is a block diagram illustrating an embodiment of a processor-based system 440 utilizing memory device 100 described above with reference to FIGS. 1-3. By way of example, but not by way of limitation, memory 446 of system 440 is constructed in accordance with the description above to include non-orthogonal word and bit lines. The processor-based system 440 may be a computer system, a process control system or any other system employing a processor and associated memory. System 440 includes a central processing unit (CPU) 441, e.g., a microprocessor that communicates with the memory 446 and an I/O device 444 over a bus 448. It is noted that bus 448 may be a series of buses and bridges commonly used in a processor-based system, but for convenience purposes only, bus 448 has been illustrated as a single bus. A second I/O device 445 is illustrated, but is not necessary to practice the invention. The processor-based system 440 can also include read-only memory (ROM) 447 and may include peripheral devices such as a floppy disk drive 442 and a compact disk (CD) ROM drive 443 that also communicates with the CPU 441 over the bus 448.

It will be appreciated by those skilled in the art that additional circuitry and control signals can be provided, and that the processor-based system 440 has been simplified to help demonstrate the present subject matter.

It is to be understood that FIG. 4 illustrates an embodiment for electronic system circuitry in which one or more memory devices, including at least one memory device with the non-orthogonal word and bit lines as discussed above, are used. The illustration of system 440, as shown in FIG. 4, is intended to provide a general understanding of one application for the structure and circuitry of the present subject matter, and is not intended to serve as a complete description of all the elements and features of an electronic system using the memory device with the non-orthogonal word and bit lines. Further, the present subject matter is equally applicable to any size and type of system 440 using the one or more memory devices with non-orthogonal word and bit lines, and is not intended to be limited to that described above. As one of ordinary skill in the art will understand, such an electronic system can be fabricated in single-package processing units, or even on a single semiconductor chip, in order to reduce the communication time between the processor and the memory device.

Applications containing the one or more memory devices with non-orthogonal word and bit lines, as described in this disclosure, include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

The present subject matter is not limited to a particular process order or structural arrangement. This application is intended to cover adaptations or variations. It is to be understood that the above description is intended to be illustrative, and not restrictive. Combinations of the above embodiments, and other embodiments, will be apparent to those of skill in the art upon reviewing the above description. The scope of the present invention should be determined with reference to the appended claims, along with the full scope of equivalents to which such claims are entitled.

What is claimed is:

1. A semiconductor memory device, comprising:
memory cells each having an area of approximately 6 square lithographic features (6F²);
word lines extending in a first direction; and
bit lines extending in a second direction,
wherein the first direction and the second direction are substantially non-orthogonal.

2. The semiconductor memory device of claim 1, wherein an angle between the first direction and the second direction is between approximately 40 and 70 degrees.

3. The semiconductor memory device of claim 2, wherein the angle between the first direction and the second direction is approximately 63 degrees.

4. The semiconductor memory device of claim 1, wherein the bit lines and the word lines are each a substantially straight line.

5. The semiconductor memory device of claim 4, wherein the word lines are at approximately 2 lithographic feature (2F) pitch.

6. The semiconductor memory device of claim 4, wherein the bit lines are at approximately 2.8 lithographic feature (2.8F) pitch.

7. A semiconductor device, comprising:
a dynamic random access memory (DRAM) circuit including:
word lines extending in a first direction; and
bit lines extending in a second direction at an angle of substantially less than 90 degrees from the first direction.

8. The semiconductor device of claim 7, wherein the DRAM circuit comprises memory cells each having an area of approximately 6 square lithographic features (6F²).

9. The semiconductor device of claim 7, wherein the DRAM circuit comprises memory cells each having an area of approximately 8 square lithographic features (8F²).

10. The semiconductor device of claim 8, wherein the angle is between approximately 40 and 70 degrees.

11. The semiconductor device of claim 10, wherein the angle is approximately 63 degrees.

12. The semiconductor device of claim 10, wherein the word lines are at approximately 2 lithographic feature (2F) pitch.

13. The semiconductor device of claim 12, wherein the bit lines are at approximately 2.8 lithographic feature (2.8F) pitch.

14. A semiconductor memory device, comprising:
dynamic random access memory (DRAM) cells including:
transistors each having a drain terminal, a source terminal, and a gate terminal; and
storage capacitors each coupled to the source terminal of one of the transistors;
word lines coupled to the gate terminals of the transistors and extending in a first direction; and
bit lines coupled to the drain terminals of the transistors and extending in a second direction substantially non-perpendicular to the first direction.

15. The semiconductor memory device of claim 14, wherein the DRAM cells each have an area of approximately 6 square lithographic features (6F²).

16. The semiconductor memory device of claim 14, wherein the DRAM cells each have an area of approximately 8 square lithographic features (8F²).

17. The semiconductor memory device of claim 14, wherein an angle between the first direction and the second direction is between approximately 40 and 70 degrees.

18. The semiconductor memory device of claim 17, wherein the angle between the first direction and the second direction is approximately 63 degrees.

19. The semiconductor memory device of claim 17, wherein the word lines are at approximately 2 lithographic feature (2F) pitch.

20. The semiconductor memory device of claim 19, wherein the bit lines are at approximately 2.8 lithographic feature (2.8F) pitch.

21. A semiconductor memory device, comprising:
a column of sense amplifiers; and
a column of memory cell arrays coupled to the column of sense amplifiers, the memory cell arrays each having an approximate surface shape of a substantially non-rectangular parallelogram.

22. The semiconductor memory device of claim 21, wherein the memory cell arrays comprise memory cells each having an area of approximately 6 square lithographic features (6F²).

23. The semiconductor memory device of claim 21, wherein the memory cell arrays comprise memory cells each having an area of approximately 8 square lithographic features (8F²).

24. The semiconductor memory device of claim 21, wherein the parallelogram has an angle in a range between approximately 40 and 70 degrees.

25. The semiconductor memory device of claim 24, wherein the parallelogram has an angle of approximately 63 degrees.

26. The semiconductor memory device of claim 21, comprising word lines running in a first direction and bit lines running in a second direction, the first direction substantially non-perpendicular to the second direction.

27. A method for making a semiconductor memory device, the method comprising:
forming memory cells each having an area of approximately 6 square lithographic features (6F²);
forming word lines extending in a first direction; and
forming bit lines extending in a second direction substantially non-perpendicular to the first direction.

28. The method of claim 27, wherein forming the bit lines comprises forming the bit lines at an angle from the word lines, wherein the angle is between approximately 40 and 70 degrees.

29. The method of claim 28, wherein the angle is approximately 63 degrees.

30. The method of claim 28, wherein forming the word lines comprises forming parallel electrically conductive lines at approximately 2 lithographic feature (2F) pitch.

31. The method of claim 28, wherein forming the bit lines comprises forming parallel electrically conductive lines at approximately 2.8 lithographic feature (2.8F) pitch.

32. The method of claim 28, wherein forming the memory cells comprises:
forming capacitors; and
forming transistors each having a drain terminal coupled to one of the bit lines, a gate terminal coupled to one of the word lines, and a source terminal coupled to one of the capacitors.

33. A method for making a semiconductor memory device, the method comprising:
forming capacitors;
forming transistors each having a drain terminal, a source terminal, and a gate terminal, the source terminal coupled to one of the capacitors;
forming word lines coupled to the gate terminals of the transistors and extending in a first direction; and
forming bit lines coupled to the drain terminals of the transistors and extending in a second direction substantially non-perpendicular to the first direction.

34. The method of claim 33, wherein forming the bit lines comprises forming the bit lines at an angle of approximately 40 to 70 degrees from the word lines.

35. The method of claim 34, wherein forming the bit lines comprises forming the bit lines at an angle of approximately 63 degrees from the word lines.

36. The method of claim 34, wherein forming the word lines comprises forming the word lines at approximately 2 lithographic feature (2F) pitch.

37. The method of claim 36, wherein forming the bit lines comprises forming the bit lines at approximately 2.8 lithographic feature (2.8F) pitch.
